(19) United States
(12) Patent Application Publication
(10) Pub. No.: US 2023/0145789 A1
(43) Pub. Date: May 11, 2023

(54) METHODS AND MATERIALS FOR MAKING ELASTOMER RESISTANT TO DEGRADATION BY ULTRAVIOLET RADIATION AND PLASMA

(71) Applicant: Applied Materials, Inc., Santa Clara, CA (US)

(72) Inventor: Mehran Moalem, Fremont, CA (US)

(21) Appl. No.: 17/953,630

(22) Filed: Sep. 27, 2022

Related U.S. Application Data
(60) Provisional application No. 63/277,021, filed on Nov. 8, 2021.

(51) Int. Cl. H01L 21/67; C08L 27/12; C08L 49/00

(52) U.S. Cl. CPC H01L 21/67115; C08L 27/12; C08L 49/00; H01L 21/67126

(57) ABSTRACT

In an additional embodiment, a semiconductor processing tool is provided. In an embodiment, the semiconductor processing tool, comprises a chamber, and a lid sealing the chamber. In an embodiment, with an elastomer seal is between the chamber and the lid. In an embodiment, the elastomer seal comprises a polymer with carbon chains, where an average number of bonds between carbons in the carbon chains is greater than 1.00. In an embodiment a portion of the processing tool is transparent to ultraviolet radiation so that the elastomer seal is exposed to the ultraviolet radiation.

### CROSS-REFERENCE TO RELATED APPLICATIONS

This application claims the benefit of U.S. Provisional Application No. 63/277,021, filed on Nov. 8, 2021, the entire contents of which is hereby incorporated by reference herein.

### BACKGROUND

### 1) Field

Embodiments relate to the field of semiconductor manufacturing and, in particular, to an elastomer material with improved ultraviolet radiation degradation resistance.

### 2) Description of Related Art

In semiconductor fabrication tools, a vacuum environment is commonly used for many different types of processes. For example, plasma based processes are implemented at sub-atmospheric pressures. In order to seal the chamber to withstand such sub-atmospheric pressures, an elastomer seal, such as an O-ring, is secured between the chamber and the lid of the tool. The elastomer seals have a useable lifespan. Before the end of useable lifespan of the elastomer seal, the elastomer seal is replaced in order to prevent leaks into the chamber.

One drawback of elastomer seals, such as polytetrafluoroethylene (PTFE) and the like, is that they are highly susceptible to damage from ultraviolet (UV) radiation. Particularly, the carbon-carbon bonds of PTFE are single bonds that have a relatively low bond energy. The photon energy of UV radiation (especially UV-B radiation and UV-C radiation) is high enough to break the carbon-carbon bonds. This results in an decrease in the useable lifespan of the elastomer seals. Particularly, in some plasma based semiconductor processing tools, components (e.g., chamber lids) may be transparent to UV radiation produced by the plasma. In some instances, the transparent component may allow for the UV radiation to reach the elastomer seal and degradation of the elastomer seal is increased.

### SUMMARY

In an embodiment, an elastomer seal is provided. In an embodiment, the elastomer seal comprises an elastomer ring. In an embodiment, the elastomer ring comprises a polymer with carbon chains, where an average number of bonds between carbons in the carbon chains is greater than 1.00.

In an additional embodiment, a semiconductor processing tool is provided. In an embodiment, the semiconductor processing tool, comprises a chamber, and a lid sealing the chamber. In an embodiment, with an elastomer seal is between the chamber and the lid. In an embodiment, the elastomer seal comprises a polymer with carbon chains, where an average number of bonds between carbons in the carbon chains is greater than 1.00. In an embodiment a portion of the processing tool is transparent to ultraviolet radiation so that the elastomer seal is exposed to the ultraviolet radiation.

In an additional embodiment, a semiconductor processing tool is provided. In an embodiment, the semiconductor processing tool, comprises a chamber, and a lid to seal the chamber. In an embodiment, the lid is transparent to one or more of UV-A radiation, UV-B radiation, and UV-C radiation. In an embodiment, an elastomer seal is between the chamber and the lid. In an embodiment, the elastomer seal comprises, a polymer with carbon chains, where an average number of bonds between carbons in the carbon chains is greater than 1.00. In an embodiment, the carbon chains are terminated with fluorine.

### BRIEF DESCRIPTION OF THE DRAWINGS

FIG. 1 is a cross-sectional illustration of a portion of a semiconductor processing tool with an elastomeric seal that is adjacent to a component that is transparent to UV radiation, in accordance with an embodiment.

FIG. 2 is an illustration of a polymerization process used to generate elastomer seals that are susceptible to UV degradation.

FIG. 3 is an illustration of a polymerization process used to generate elastomer seals that have an average number of bonds between carbons in a carbon chain that is approximately 1.5, in accordance with an embodiment.

FIG. 4 is an illustration of a polymerization process used to generate elastomer seals that have an average number of bonds between carbons in a carbon chain that is approximately 1.67, in accordance with an embodiment.

FIG. 5 illustrates a block diagram of an exemplary computer system that may be used in conjunction with a processing tool, in accordance with an embodiment.

### DETAILED DESCRIPTION

Systems described herein include an elastomer material with improved ultraviolet radiation degradation resistance. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, elastomer seals are susceptible to UV degradation that results in a decrease in the useable life of the elastomer seal. As such, material costs and labor costs (to switch out the seal) for semiconductor processing tools are increased. Shorter useable life may also result in shorter times between planned maintenance, and result in increases in tool down time. These effects are especially problematic when the elastomer seal is directly exposed to UV radiation through a transparent component, such as a chamber lid or viewport window.

Generally, the UV radiation has a photon energy that is greater than the bond energy of a single carbon-carbon bond. As such, the UV radiation results in the breaking of the carbon-carbon bonds in the polymer chains and results in a more brittle material that is not suitable for maintaining sub-atmospheric conditions within the chamber. Existing elastomer materials, such as polytetrafluoroethylene (PTFE) have a polymer structure with long carbon chains that include singly-bonded carbon atoms. As such, there is not much protection from the damage caused by the UV radiation.

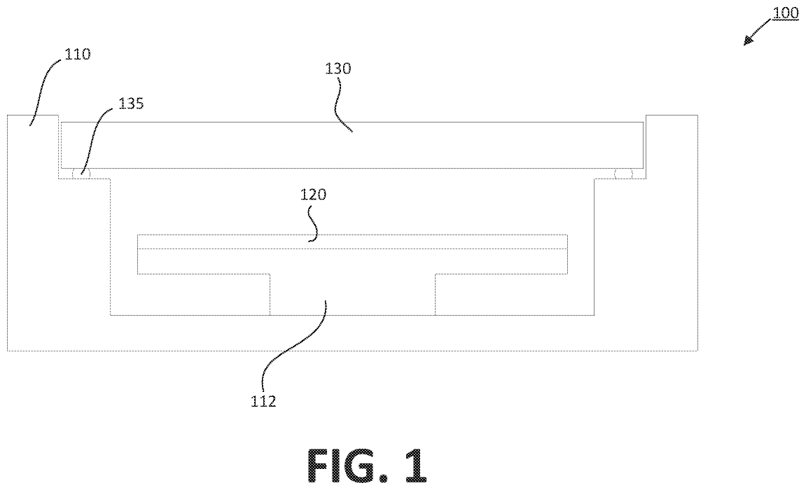

Referring now to FIG. 1, a cross-sectional illustration of portion of a semiconductor processing tool 100 is shown, in accordance with an embodiment. As shown, the tool 100 includes a chamber 110. The chamber 110 may comprise a pedestal 112 on which a substrate 120 is secured (e.g., with a vacuum chuck, an electrostatic chuck, or the like). The substrate 120 may be a semiconductor substrate, such as a silicon wafer or any other type of wafer. In other embodiments, non-semiconductor substrates may also be provided in the chamber 110. For example, glass substrates 120 may be present in some processing tools 100.

In an embodiment, a lid 130 may seal the chamber 110. An elastomer seal 135 may be pressed between the lid 130 and a surface 111 of the chamber 110. In an embodiment, the elastomer seal 135 (e.g., an O-ring) may be a polymer that is resistant to UV radiation. For example, the elastomer seal 135 may comprise a polymer with carbon chains, where the average number of bonds between the carbon atoms is greater than 1. That is, some of the carbon-carbon bonds may be double bonds. In some embodiments, the average number of bonds between the carbon atoms may be approximately 1.5 or greater, or approximately 1.66 or greater. In a particular embodiment, the elastomer seal 135 may comprise polytetrafluoropropadiene or polydifluoroacetylene.

Increasing the average number of bonds between the carbon atoms reduces the damage caused by UV radiation. Particularly, the increased number of bonds increases the bond energy and hence the strength of bond between the carbon atoms. The increased bond energy may be greater than the photon energy of the UV radiation. As such, exposure to the UV radiation may not result in the breaking of the carbon-carbon bonds, as is the case with existing elastomer seals.

In an embodiment, one or more components of the semiconductor processing tool 100 may comprise a material that is transparent to UV radiation. For example, the lid 130 may be transparent to UV radiation. As an example, the lid 130 may comprise sapphire. The use of a material that is transparent to UV radiation may result in greater UV exposure of the elastomer seal 135. Elastomer seals 135 in accordance with embodiments disclosed herein allow for improved lifespan despite the increased exposure.

In an embodiment, the semiconductor processing tool 100 is a plasma processing tool. For example, the semiconductor processing tool 100 may be a remote plasma source (RPS) processing tool 100. In such an embodiment, the plasma may be struck in a chamber (not shown) that is external to the chamber 110. In other embodiments, the semiconductor processing tool 100 is a plasma processing tool 100, where the plasma is struck in the chamber 110. While plasma sources may result in UV exposure, other types of chambers may also result in UV exposure as well. For example, in a radical oxidation chamber, lamps over the lid 130 may expose the elastomer seal 135 with UV radiation. Furthermore, while the lid 130 is described as the UV transparent component, it is to be appreciated that any component of the semiconductor processing tool 100 may be transparent to UV radiation and result in an increased UV radiation exposure of the elastomer seal 135.

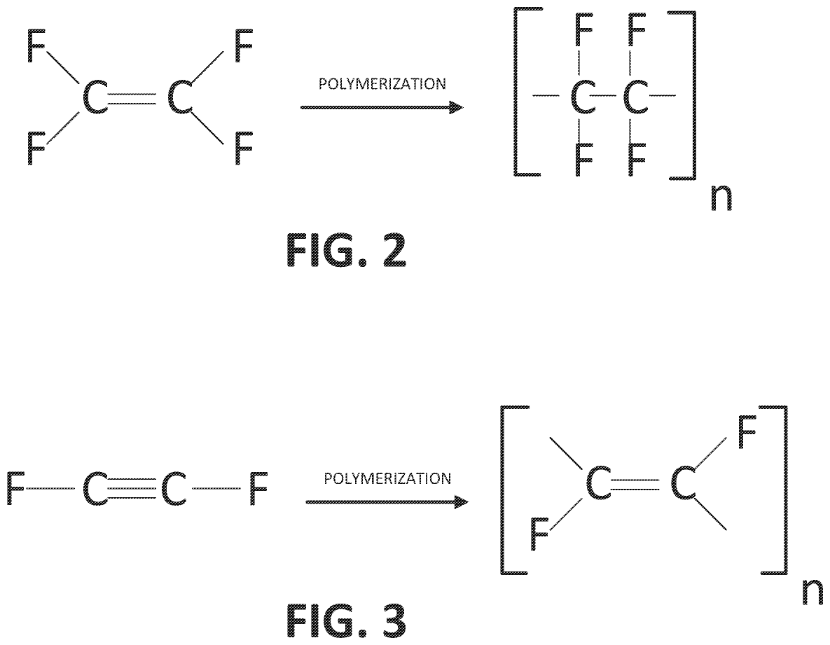

Referring now to FIG. 2, an illustration of the polymerization process to form PTFE is shown. As illustrated, the monomers that are polymerized may be tetrafluoroethylene. Tetrafluoroethylene includes a carbon-carbon double bond, with each of the carbons further bonded to a pair of fluorine atoms. A polymerization process, as indicated by the arrow, results in a breaking of the double bond and replacing the double bond with a single bond to another carbon. That is, each of the carbon atoms are bonded to two carbon atoms and two fluorine atoms.

The drawback of such a structure is that the single bonded carbon-carbon linkages have a lower bond energy. For example, the single bonds between carbon atoms may have a bond energy of around 3 eV. Unfortunately, UV radiation (particularly, UV-B radiation and UV-C radiation) has a higher photon energy than 3 eV. As such, the PTFE is susceptible to UV damage upon exposure.

Accordingly, embodiments disclosed herein include an elastomer seal with a higher average number of bonds between the carbon-carbon linkages. By increasing the average number of bonds, the bond energy is increased so that the bond energy is greater than the photon energy of the UV radiation. As such, the UV radiation leaves the bonds substantially undamaged and the UV degradation is significantly reduced.

Referring now to FIG. 3, an illustration of the polymerization to form polydifluoroacetylene is shown, in accordance with an embodiment. As shown, the monomers that are polymerized are difluoroacetylene. Difluoroacetylene includes a pair of carbon atoms that are bonded to each other with a triple bond. Each carbon is also bonded to a fluorine atom.

As indicated by the arrow, a polymerization process is implemented on the monomers to form the polymer. In an embodiment, the polymerization process may be any suitable polymerization process common to elastomer manufacturing. For example, the polymerization process may include a high temperature and/or high pressure polymerization. A high temperature process may refer to a temperature that is approximately 300° Celsius or greater. In some embodiments, catalysts may also be used to improve the polymerization.

As shown on the right side of the illustration, the polydifluoroacetylene includes a double bonded carbon-carbon linkage. Each of the carbons are also bonded to an additional carbon atom and a fluorine atom with a single bond. As such, half of the carbon-carbon bonds are double bonds, and the other half of the carbon-carbon bonds are single bonds. This provides an average number of bonds that is approximately 1.5 bonds between each carbon-carbon linkage. The bond energy of 1.5 bonds is greater than the photon energy of UV radiation, and results in less UV degradation.

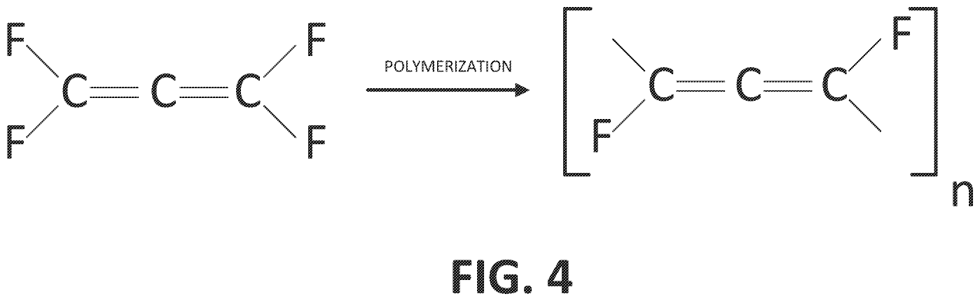

Referring now to FIG. 4, an illustration of the polymerization to form polytetrafluoropropadiene is shown, in accordance with an embodiment. As shown, the monomers that are polymerized are tetrafluoropropadiene. Tetrafluoropropadiene includes three carbon atoms that are bonded to each other with double bonds. The center carbon is double bonded to two additional carbon atoms, and the outer carbons are double bonded to the center carbon and to two fluorine atoms.

As indicated by the arrow, a polymerization process is implemented on the monomers to form the polymer. In an embodiment, the polymerization process may be any suitable polymerization process common to elastomer manufacturing. For example, the polymerization process may include a high temperature and/or high pressure polymerization. A high temperature process may refer to a temperature that is approximately 300° Celsius or greater. In some embodiments, catalysts may also be used to improve the polymerization.

As shown on the right side of the illustration, the polytetrafluoropropadiene comprises a carbon chain with three carbon atoms that are double bonded to each other. The inner carbon atom is double bonded to both of the outer carbon atoms. The outer carbon atoms are singly bonded to another carbon atom and a fluorine atom. As such, the average number of bonds between the carbon atoms is approximately 1.66 or greater. The bond energy of 1.66 bonds is greater than the photon energy of UV radiation, and results in less UV degradation.

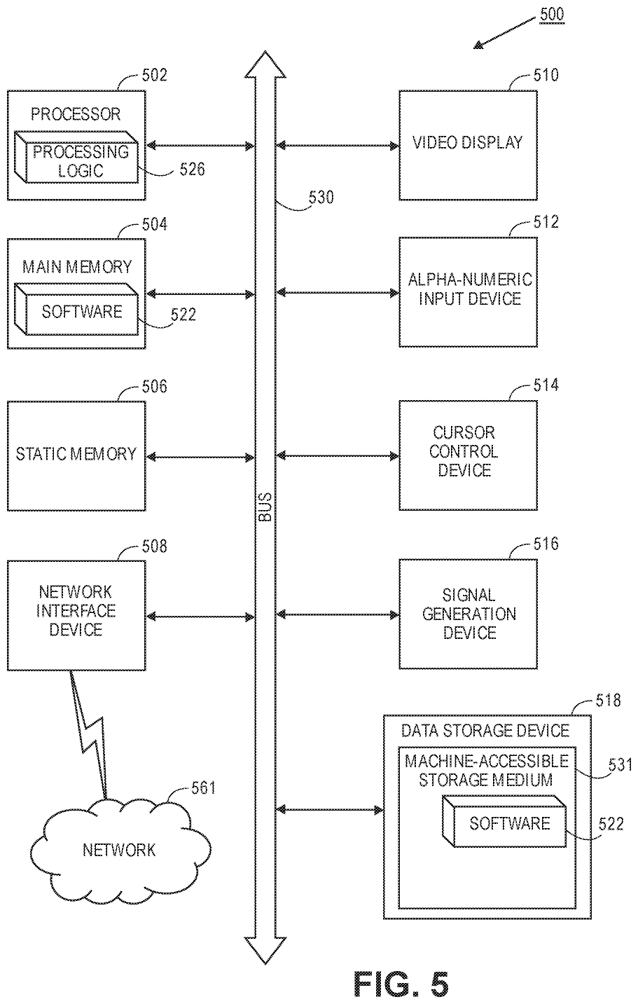

Referring now to FIG. 5, a block diagram of an exemplary computer system 500 of a processing tool is illustrated in accordance with an embodiment. In an embodiment, computer system 500 is coupled to and controls processing in the processing tool. Computer system 500 may be connected (e.g., networked) to other machines in a Local Area Network (LAN), an intranet, an extranet, or the Internet. Computer system 500 may operate in the capacity of a server or a client machine in a client-server network environment, or as a peer machine in a peer-to-peer (or distributed) network environment. Computer system 500 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 500, the term “machine” shall also be taken to include any collection of machines (e.g., computers) that individually or jointly execute a set (or multiple sets) of instructions to perform any one or more of the methodologies described herein.

Computer system 500 may include a computer program product, or software 522, having a non-transitory machine-readable medium having stored thereon instructions, which may be used to program computer system 500 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 500 includes a system processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

System processor 502 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 502 may also be one or more special-purpose processing devices such as an application specific integrated circuit (ASIC), a field programmable gate array (FPGA), a digital signal system processor (DSP), network system processor, or the like. System processor 502 is configured to execute the processing logic 526 for performing the operations described herein.

The computer system 500 may further include a system network interface device 508 for communicating with other devices or machines. The computer system 500 may also include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium 532 (or more specifically a computer-readable storage medium) on which is stored one or more sets of instructions (e.g., software 522) embodying any one or more of the methodologies or functions described herein. The software 522 may also reside, completely or at least partially, within the main memory 504 and/or within the system processor 502 during execution thereof by the computer system 500, the main memory 504 and the system processor 502 also constituting machine-readable storage media. The software 522 may further be transmitted or received over a network 520 via the system network interface device 508. In an embodiment, the network interface device 508 may operate using RF coupling, optical coupling, acoustic coupling, or inductive coupling.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An elastomer seal, comprising:
an elastomer ring, wherein the elastomer ring comprises a polymer with carbon chains, wherein an average number of bonds between carbons in the carbon chains is greater than 1.00.

2. The elastomer seal of claim 1, wherein the average number of bonds is 1.50 or greater.

3. The elastomer seal of claim 1, wherein the average number of bonds is 1.66 or greater.

4. The elastomer seal of claim 1, wherein the polymer is polytetrafluoropropadiene.

5. The elastomer seal of claim 1, wherein the polymer is polydifluoroacetylene.

6. The elastomer seal of claim 1, wherein a polymerization process to form the polymer is a high temperature polymerization.

7. The elastomer seal of claim 6, wherein the high temperature is approximately 300° C. or greater.

8. The elastomer seal of claim 1, wherein a polymerization process to form the polymer includes the use of a catalyst.

9. The elastomer seal of claim 1, wherein an average bond energy of bonds between carbons in the carbon chains is greater than 3 eV.

10. A semiconductor processing tool, comprising:
a chamber; and
a lid sealing the chamber with an elastomer seal between the chamber and the lid, wherein the elastomer seal comprises a polymer with carbon chains, wherein an average number of bonds between carbons in the carbon chains is greater than 1.00, and wherein a portion of the processing tool is transparent to ultraviolet radiation so that the elastomer seal is exposed to the ultraviolet radiation.

11. The semiconductor processing tool of claim 10, wherein the lid is transparent to ultraviolet radiation.

12. The semiconductor processing tool of claim 11, wherein the lid comprises sapphire.

13. The semiconductor processing tool of claim 10, wherein the semiconductor processing tool is a remote plasma source processing tool.

14. The semiconductor processing tool of claim 10, wherein the average number of bonds is 1.50 or greater.

15. The semiconductor processing tool of claim 10, wherein the average number of bonds is 1.66 or greater.

16. The semiconductor processing tool of claim 10, wherein the polymer is polytetrafluoropropadiene.

17. The semiconductor processing tool of claim 10, wherein the polymer is polydifluoroacetylene.

18. A semiconductor processing tool, comprising:
a chamber;
a lid to seal the chamber, wherein the lid is transparent to one or more of UV-A radiation, UV-B radiation, and UV-C radiation;
an elastomer seal between the chamber and the lid, wherein the elastomer seal comprises:
a polymer with carbon chains, wherein an average number of bonds between carbons in the carbon chains is greater than 1.00, and wherein the carbon chains are terminated with fluorine.

19. The semiconductor processing tool of claim 18, wherein the polymer comprises polytetrafluoropropadiene or polydifluoroacetylene.

20. The semiconductor processing tool of claim 18, wherein the average number of bonds is 1.50 or greater.
